(19) United States
(12) Patent Application Publication
(10) Pub. No.: US 2019/0348486 A1
(43) Pub. Date: Nov. 14, 2019

(54) DISPLAY DEVICE

(71) Applicant: Japan Display Inc., Tokyo (JP)

(72) Inventor: Masakazu GUNJI, Tokyo (JP)

(21) Appl. No.: 16/394,079

(22) Filed: Apr. 25, 2019

(30) Foreign Application Priority Data
May 11, 2018 (JP) 2018-092303

(51) Int. Cl. H01L 27/32; H01L 51/52

(52) U.S. Cl. CPC H01L 27/3258; H01L 27/3211; H01L 2251/301; H01L 51/5262; H01L 27/323; H01L 51/5253

(57) ABSTRACT

A display device includes a light emitting layer emitting light in response to a supplied electric current, a first insulating layer having a first refractive index arranged on a light path, a second insulating layer including a first portion arranged in contact with the first insulating layer on the opposite side of the light emitting layer with respect to the first insulating layer, and a second portion arranged further from the first insulating layer than the first portion, a second refractive index increases to a third refractive index in the first portion the further away from the first insulating layer, the third refractive index decreases to a fourth refractive index in the second portion the further away from the first insulating layer, and a refractive index continuously changes in at least one portion of the first portion and at least one portion of the second portion.

### CROSS-REFERENCE TO RELATED APPLICATIONS

This application is based upon and claims the benefit of priority from the prior Japanese Patent Application No. 2018-092303, filed on May 11, 2018, the entire contents of which are incorporated herein by reference.

### FIELD

The present invention relates to a display device.

### BACKGROUND

A display device includes a structure in which a plurality of films having light-transmissivity are stacked. When films having different refractive indexes are stacked, light reflects onto the interfaces thereof. It is necessary that a stacked structure is designed appropriately in order to efficiently bring reflected light to the outer portion thereof. Particularly, characteristics of the stacked films (film thickness, refractive index, and the like) are important elements. In Japanese Laid-Open Patent Publication Number 2017-152252, a stacked structure is provided so as to minimize the difference between the refractive indexes of a sealing layer and a resin layer by suppressing the reflection of light onto the interfaces of the sealing layer and the resin layer.

### SUMMARY

According to an embodiment of the present invention, a display device is provided including a light emitting layer emitting light in response to a supplied electric current, a first insulating layer arranged above an optical path of light emitted from the light emitting layer and having a first refractive index, a second insulating layer including a first portion arranged in contact with the first insulating layer on the opposite side of the light emitting layer with respect to the first insulating layer, and a second portion arranged further from the first insulating layer than the first portion, a second refractive index increases to a third refractive index in the first portion the further away from the first insulating layer, the third refractive index decreases to a fourth refractive index in the second portion the further away from the first insulating layer, and refractive indexes continuously change in at least one portion of the first portion and at least one portion of the second portion.

According to another embodiment of the present invention, a display device is provided including a light emitting layer emitting light in response to a supplied electric current, a first insulating layer arranged above an optical path of light emitted from the light emitting layer, a second insulating layer including a first portion arranged in contact with the first insulating layer on the opposite side of the light emitting layer with respect to the first insulating layer, and a second portion arranged further from the first insulating layer than the first portion, a ratio of nitrogen to oxygen increases in the first portion the further away from the first insulating layer, the ratio of nitrogen to oxygen decreases in the second portion the further away from the first insulating layer, and this ratio continuously changes in at least one portion of the first portion and at least one portion of the second portion.

### BRIEF DESCRIPTION OF DRAWINGS

FIG. 1 is a diagram describing the structure of a display device according to a first embodiment of the present invention;

FIG. 2 is a schematic diagram showing a cross-sectional structure of a display device according to a first embodiment of the present invention;

FIG. 3 is a diagram describing the structure of an optical adjustment layer according to the first embodiment of the present invention;

FIG. 4 is a diagram describing characteristics of a first inorganic sealing layer according to the first embodiment of the present invention, and

FIG. 5 is a diagram describing characteristics of a first inorganic sealing layer according to a second embodiment of the present invention.

### DESCRIPTION OF EMBODIMENTS

Hereinafter, embodiments of the present invention will be described below with reference to the drawings. The disclosure herein is merely an example, and appropriate modifications within the gist of the present invention which may be easily conceived by those skilled in the art are naturally included within the scope of the invention. The accompanying drawings schematically illustrate width, thickness, shape, or other characteristics of each portion for clarity, with respect to actual configurations. However, these schematic drawings are merely examples and do not limit the scope of the present invention. In the present specification and each of the drawings, elements identical or similar to those shown previously are denoted by similar symbols, thus, detailed descriptions thereof are omitted accordingly.

Furthermore, in the detailed description of the present invention, when a structural element is described as being “above” (or on) or “below” (or under) another structural element, it is not limited to cases in which a structural element is directly above (or on) or directly below (or under) another structural element, and also includes cases in which further another structural element is included between the structural element above (or on) or below (or under) the other structural element, unless otherwise specified.

### First Embodiment

### [Structural Outline]

A display device according to the first embodiment of the present invention is a display device using an OLED (Organic Light Emitting Diode). The display device of this example provides a color display using a plurality of OLED which emit various different colors. In this example, an OLED emitting a red-colored (R) light, an OLED emitting a green-colored (G) light, and an OLED emitting a blue-colored (B) light are used. Furthermore, an OLED emitting different colored lights such as an OLED emitting a white-colored (W) light or the like may also be used.

When the display device is provided with light-emitting elements such as an OLED or the like, by appropriately designing a stacked structure in order to use light interference, a higher rate of light extraction may be attempted. In such a case, since a complicated stacked layer structure is used, it becomes extremely difficult to design the stacked layer structure. Additionally, there are layers which must also be included in the stacked structure, such as a layer preventing the penetration of moisture which causes light emitting elements to deteriorate. Due to the existence of such layers, the stacked layer structure becomes more difficult to design.

Here, an example of a display device including a structure which is simply designed so as to decrease reflection on the interfaces of adjacent films will be described below.

The display device has a structure in which a first substrate and a second substrate are bonded by an adhesive material. Driving elements such as a thin film transistor (TFT) are arranged above the first substrate in order to control the light emission condition of the OLED. The second substrate is a substrate which becomes a cover protecting elements formed above the first substrate. Furthermore, when a cover layer is directly formed so as to cover elements formed above the first substrate, the second substrate serving as a cover may be unnecessary.

A top emission type is used in which light from the OLED arranged above the first substrate is emitted onto the opposite side of the first substrate, passes through the second substrate, and is visible to the user. That is to say, the second substrate side is a display surface. The display device is equipped with a touch sensor function which detects contact on the display surface.

Within the display device, light from the OLED passes through a plurality of layers which are formed of a light-transmissive material. Light from the OLED reflects in the interface of each layer due to the differences of the refractive indexes. In the display device described in detail below, a stacked structure is arranged so as to extract as much of this light as possible to the outer portion of the display device.

### [Structure of Display Device]

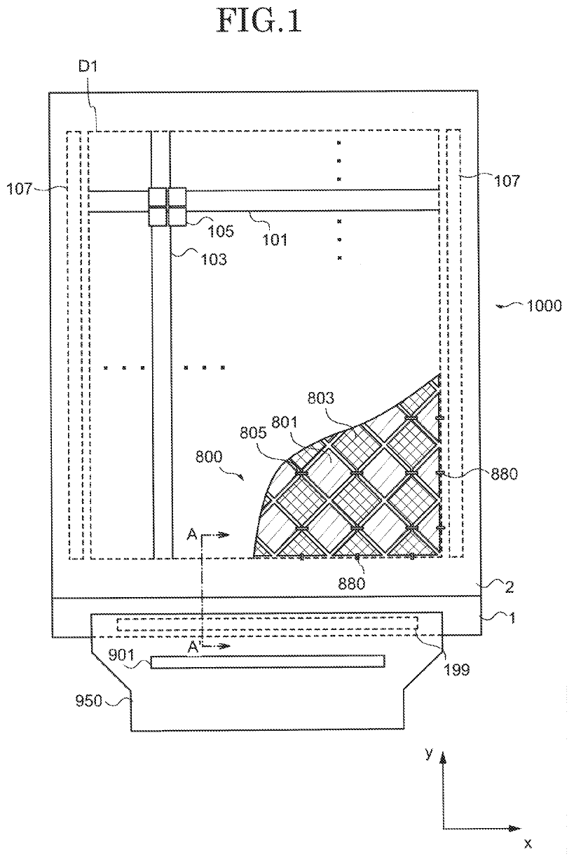

FIG. 1 is a diagram describing the structure of a display device according to the first embodiment of the present invention. A display device 1000 is equipped with a first substrate 1, a second substrate 2 adhered to the first substrate 1, and an FPC (Flexible Printed Circuit) 950 connected to a terminal region 199 of the first substrate 1. The terminal region 199 has a plurality of connection terminals arranged in a line. A driver IC 901 is mounted on the FPC 950.

The first substrate 1 of the display device 1000 includes a display region D1 and a region in which a driving circuit 107 is arranged. A scanning line 101 extending in an x direction, and a data signal line 103 extending in a y direction which is a different direction to the x direction, are arranged in the display region D1. The scanning line 101 is arranged along the y direction. The data signal line 103 is arranged along the x direction.

In this example, the x direction and the y direction intersect perpendicularly. A pixel 105 is arranged in a position corresponding to a portion in which the scanning line 101 and the data signal line 103 intersect. The pixel 105 is arranged along the x direction and the y direction. Furthermore, one signal line extending along the x direction and one extending along the y direction with respect to one pixel 105 is shown in FIG. 1, however, there may be more than two lines each. Additionally, wires supplying a designated voltage of an electricity supply line or the like may be arranged in the display region D1.

The driving circuit 107 is arranged in an area surrounding the display region D1 and supplies a designated signal to the scanning line 101. In this example, the driver IC 901 controls the driving circuit 107 based on the signal input from a controller of the outer portion while supplying a video signal or the like to the data signal line 103. Furthermore, other driving circuits may further be provided in the periphery of the display region D1.

A display element including a pixel circuit and a light emitting element (OLED) is arranged in each pixel 105. The pixel circuit, for example, includes a thin film transistor and a capacitor. The light emitting element includes a light emitting region emitting light by controlling the pixel circuit. In this example, the light emitting region of each pixel 105 emits light in red, green, or blue.

The pixel circuit controls the light emission of the light emitting element by each signal of a control signal supplied by the scanning line 101 and a video signal supplied by the data signal line 103 or the like. Images are displayed in the display region D1 by controlling this emission of light. Light from the light emitting elements passes through the second substrate 2 and is visible to the user as an image on the display surface side.

Furthermore, a touch sensor 800 is arranged in the display region D1. In FIG. 1, only a portion of the touch sensor 800 is shown so as to simplify the description of the relationship between other structures. The touch sensor 800 is arranged further to the second substrate 2 side than the light emitting region of the pixel 105. For this reason, light from the light emitting element is visible to the user on the display surface by passing through the second substrate 2 as described above after passing through a plurality of layers such as layers provided in a first inorganic sealing layer 620 and a touch sensor 800 to be described later. A retrieval wire 880 is used in order to connect a first sensor electrode 801 and a second sensor electrode 803 to the connection terminal of the terminal region 199.

The first sensor electrode 801 and the second sensor electrode 803 are electrodes each having an outer portion along the outer edge of an approximately square shaped outer edge in which the x direction and the y direction are diagonal. However, each has an opening portion in a location corresponding to the light emitting region. For this reason, by arranging the first sensor electrode 801 and the second sensor electrode 803 in places corresponding to locations other than the light emitting region, the first sensor electrode 801 and the second sensor electrode 803 each have a so-called mesh-like conductor. For this reason, even if the first sensor electrode 801 is formed by a metal having light blocking properties, light from the light emitting region may pass through toward the display surface via the opening portion. Furthermore, the second sensor electrode 803 has a similar structure to the first sensor electrode 801, that is to say, it has a mesh-like conductor.

### [Cross-Sectional Structure of Display Device]

In continuation, a cross-sectional structure of the display device 1000 in the area including the region from the display region D1 to the terminal region 199 shown in FIG. 1 will be described.

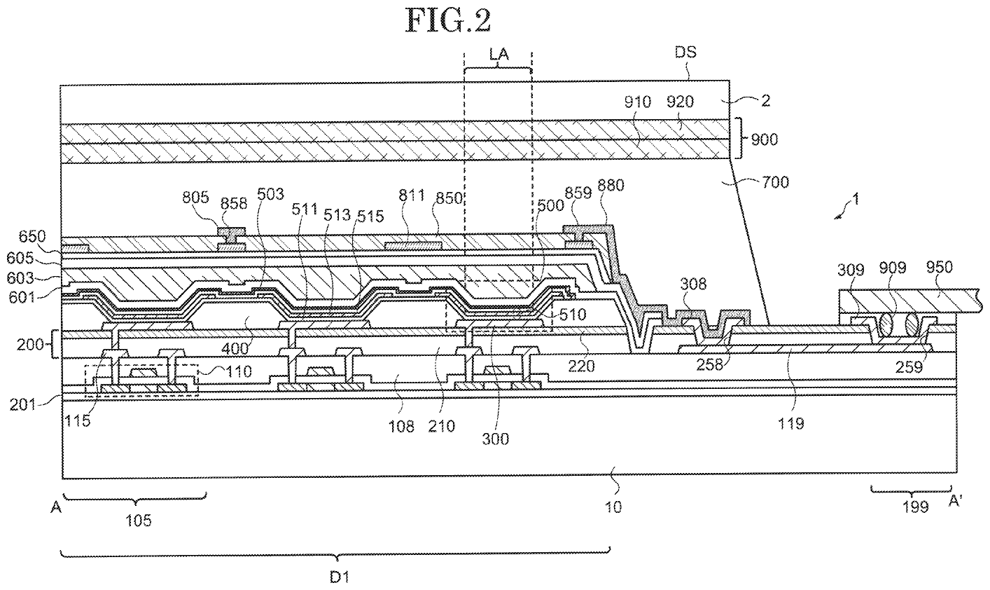

FIG. 2 is a schematic diagram showing a cross-sectional structure of a display device according to the first embodiment of the present invention. The cross-sectional structure described below is shown as an end view taken along line A-A′ shown in FIG. 1. A first support substrate 10 in the first substrate 1 and the second substrate 2 are organic resin substrates having flexibility. Furthermore, one or both of the first support substrate 10 and the second substrate 2 may be glass substrates.

A thin film transistor 110 is located above the first support substrate 10 via an insulating layer 201 of silicon oxide, silicon nitride, or the like. The thin film transistor 110 uses amorphous silicon or crystallized silicon as a semiconductor layer. Furthermore, the semiconductor layer may be a light-transmissive metal oxide semiconductor of InGaZnO or the like.

Interlayer insulating layers 108 and 200 having an insulating surface are arranged so as to cover the thin film transistor 110. A pixel electrode 300 is arranged above the interlayer insulating layer 200. In this example, the interlayer insulating layer 200 is a stacked structure including an organic insulating layer 210 of acrylic resin or the like, and an inorganic insulating layer 220 of silicon nitride (SiN) or the like. The inorganic insulating layer 220 is located further to the pixel electrode 300 side than the organic insulating layer 210.

The pixel electrode 300 is arranged corresponding to each pixel 105, and is connected to a conductive layer 115 via a contact hole 250 provided in the interlayer insulating layer 200. The conductive layer 115 is connected to the thin film transistor 110 via the interlayer insulating layer 108, and is formed of a stacked layer structure in which aluminum (Al) is sandwiched by titanium (Ti), for example. The pixel electrode 300 is used as an OLED anode electrode. Because the display device 1000 displays images by a top emission method, the pixel electrode 300 may not have light transmissivity. In this example, the pixel electrode 300 includes layers such as a layer reflecting light emitted by the OLED (for example, a metal including silver), and a layer in which conductive metal oxides having light transmissivity on ae surface which is in contact with the OLED (for example, ITO: Indium Tin Oxide).

A bank layer 400 covers the edge portion of the pixel electrode 300 and spaces between adjacent pixels, and provides an opening portion exposing a portion of the pixel electrode 300. In this example, the bank layer 400 is formed of organic insulating materials such as acrylic resin.

A light emitting portion 510 is an OLED which covers and is in contact with the pixel electrode 300 and a portion of the bank layer 400. The light emitting portion 510 has a stacked layer structure in which a plurality of organic materials are stacked. In this example, the light emitting portion 510 has a stacked structure including a hole injection/transport layer 511, a light emitting layer 513, and an electron injection/transport layer 515. The light emitting layer 513 emits light in response to a supplied electric current. The light emitting layer 513 has different compositions corresponding to each color of emitted light (red, green, and blue). The light emitting layer 513 is separated above the bank 400 in adjacent pixels corresponding to different colors.

A light transmissive electrode 503 covers the light emitting portion 510 and forms a cathode electrode (counter-pixel electrode corresponding to pixel 300) of the OLED. The light transmissive electrode 503 is an electrode through which light from the OLED passes, and for example, uses a metal layer or the like thin enough so light may pass through, or a light transmissive conductive metal oxide. A light emitting element 500 having a light emitting region LA is formed by the pixel electrode 300, the light emitting portion 510, and the light transmissive electrode 503. This light emitting region LA corresponds to the region of pixel 300 which is exposed by the bank layer 400.

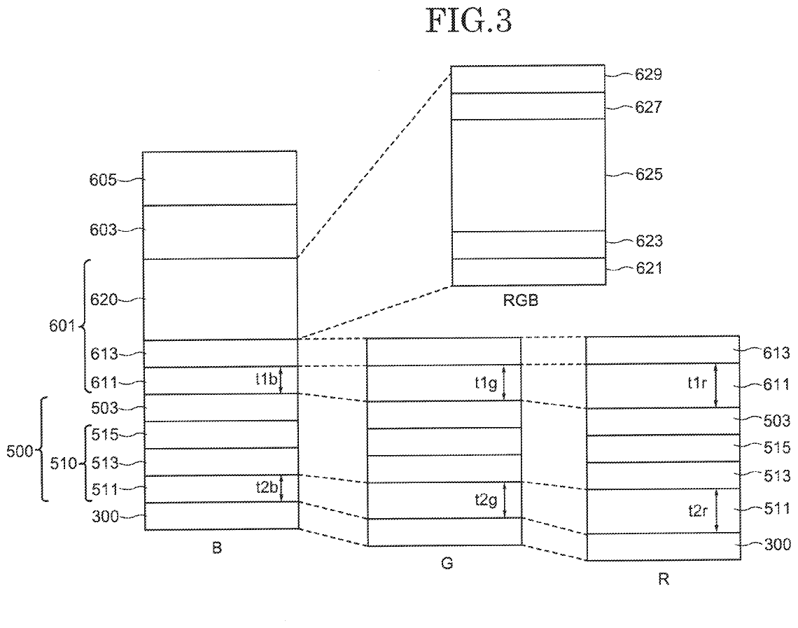

An optical adjustment layer 601 is a layer for improving the extraction rate efficiency of light from the light emitting layer 513 while inhibiting moisture, gas, or other elements which deteriorate the light emitting portion 510 from reaching the light emitting portion 510. In this example, the optical adjustment layer 601 is arranged covering the light emitting element 500 while covering the entire display region. The optical adjustment layer 601 includes a high refractive index layer 611, a low refractive index layer 613, and a first inorganic sealing layer 620 (see FIG. 3). The first inorganic sealing layer 620 mainly has the function to inhibit elements which deteriorate the light emitting portion 510 from reaching the light emitting portion 510. On the other hand, the high refractive index layer 611 and the low refractive index layer 613 have the function to improve extraction rate efficiency of light. The details of the structure of the optical adjustment layer 601 will be described below.

An organic sealing layer 603 is an organic insulating layer of acrylic resin or the like arranged above the optical adjustment layer 601. A second inorganic sealing layer 605 is an inorganic insulating layer of silicon nitride or the like arranged above the organic sealing layer 603. The organic sealing layer 603 and the second inorganic sealing layer 605 function as layers which work with the first inorganic sealing layer 620 to inhibit elements which deteriorate the light emitting portion 510 from reaching the light emitting portion 510. The organic insulating layer 650 covers the second inorganic sealing layer 605.

A conductive portion 811 is arranged above the organic insulating layer 650. The conductive portion 811 is formed of a stacked structure of aluminum Al sandwiched by titanium (Ti), for example. Furthermore, the conductive portion 811 is formed of a metal having light blocking properties, however, may also be formed of a material having less light blocking properties than that of a metal (highly light-transmissive materials), for example, a conductive metal oxide.

As described above, the conductive portion 811 is a conductive part arranged in a mesh-like shape composing the first sensor electrode 801 and the second sensor electrode 803. An insulating layer 850 covers the conductive portion 811. The insulating layer 850 includes an inorganic insulating layer of silicon oxide, silicon nitride, or the like.

A connection electrode 805 is arranged above the insulating layer 850, and is connected to the conductive portion 811 via a contact hole 858 formed in the insulating layer 850. The connection electrode 805 is connected to a portion of the conductive portion 811 so as to connect adjacent first sensor electrodes 801. A retrieval wire 880 is arranged above the insulating layer 850 and is connected to the conductive portion 811 via a contact hole 859 formed in the insulating layer 850. Furthermore, the vertical relationship between the conductive portion 811 and the connection electrode 805 may be reversed.

The retrieval wire 880 is electrically connected to a terminal wiring 119 covered by a protective electrode 308 via a contact hole 258 formed in the interlayer insulating layer 200. The protective electrode 308 may be formed of the same material as the pixel electrode 300. A portion of the terminal wiring 119 exposed by the contact hole 259 in the terminal region 199 is covered by the protective electrode 309. This portion is a part of the connection terminal in the terminal region 199. The FPC 950 is electrically connected to the connection terminal via an anisotropic conductive layer 909.

An organic protective film 700 is filled between and is a material bonding the first substrate 1 and the second substrate 2 together, and, for example, is an acrylic resin having light transmissivity. In this example, a circular polarizing plate 900 is arranged between the second substrate 2 and the organic protective film 700. The circular polarizing plate 900 has a stacked layer structure including a quarter wave plate 910 and a linear polarizing plate 920. Light from the light emitting region LA is emitted from the display surface DS of the second substrate 2 to the outer portion by this structure. The above is a description of the cross-sectional structure of the display device 1000.

### [Structure of Optical Adjustment Layer]

In continuation, details of the structure of the optical adjustment layer 601 will be described.

FIG. 3. is a diagram describing the structure of the optical adjustment layer according to the first embodiment of the present invention. FIG. 3 shows not only the optical adjustment layer 601 in the light emitting region LA, but also the structures arranged below the optical adjustment layer 601 (pixel electrode 300, light emitting portion 510, and light transmissive electrode 503) and the structures arranged above the optical adjustment layer 601 (organic sealing layer 603). The light from the light emitting portion 510 (light emitting layer 513) passes through the light transmissive electrode 503, the optical adjustment layer 601, and the organic sealing layer 603 in order. That is to say, the optical adjustment layer 601 is arranged above the path of this light.

The optical adjustment layer 601 includes the high refractive index layer 611, the low refractive layer 613, and the first inorganic sealing layer 620. The high refractive layer 611 is an organic material arranged above the light transmissive electrode 503. The high refractive index layer 611 preferably uses materials having refractive indexes of 1.8˜2.1. The thickness of the high refractive index layer 611 is approximately 50 nm˜200 nm and differs according to the color of light shown from the light emitting layer 513. For example, the shorter the wavelength of light emitted from the light emitting layer 513, the thinner the thickness of the high refractive index layer 611 will be above that path of light. As shown in FIG. 3, when the thickness of the high refractive index layer 611 corresponding to blue (B) is t1b, the thickness of the high refractive index layer 611 corresponding to green (G) t1g, and the thickness of the high refractive index layer 611 corresponding to red (R) is t1r, a t1b<t1g<t1r relationship is attained. Furthermore, in this example, as shown in FIG. 3, the injection/transport layer 511 also has the same relationship as the high refractive index layer 611. That is to say, when the thickness of the hole injection/transport layer 511 corresponding to blue color (B) is t2b, the thickness of the hole injection/transport layer 511 corresponding to green (G) is t2g, and the thickness of the hole injection/transport layer 511 corresponding to red (R) is t2r, a t2b<t2g<t2r relationship is attained.

The low refractive index layer 613 is an inorganic insulating layer arranged in contact with and above the high refractive index layer 611. In this example, the low refractive index layer 613 is lithium fluoride (LiF). The refractive index of the low refractive index layer 613 is 1.3˜1.4 and is lower than the refractive index of the high refractive index layer 611. The thickness of the low refractive index layer 613 is 80˜100 nm. By making the disparity between the refractive indexes of the high refractive index layer 611 and the low refractive index layer 613 greater, the reflection of light on these interfaces also becomes greater. The particular wavelength of light injected from the high refractive index layer 611 to the low refractive index layer 613 is emphasized by interference depending on the optical path of the reflected light. In order to achieve this emphasized effect, as described above, the shorter the wavelength of light emitted from the light emitting layer 513, the thinner the thickness of the high refractive index layer 611 and the hole injection/transport layer 511 will be above the path of light.

The first inorganic sealing layer 620 is an inorganic insulating layer arranged above the low refractive index layer 613. In other words, the first inorganic sealing layer 620 is arranged in contact with the low refractive index layer 613 on the opposite side of the light emitting layer 513 with respect to the low refractive index layer 613. The details of the structure of the first inorganic sealing layer 620 will be described below. The organic sealing layer 603 is arranged above the inorganic sealing layer 620. The refractive index of the organic sealing layer 603 is 1.4˜1.6.

### [Structure of First Inorganic Sealing Layer]

The first inorganic sealing layer 620 includes a first low refractive index portion 621, a first slanted portion 623, a high refractive index portion 625, a second slanted portion 627, and a second low refractive index portion 629. In this example, the first low refractive index portion 621 and the second low refractive index portion 629 are silicon oxide (SiO). The high refractive index portion 625 is silicon nitride (SiN). The first slanted portion 623 is silicon oxynitride (SiON). In the first slanted portion 623, the ratio of nitrogen (N) to oxygen (O) continuously increases from the low refractive index portion 621 toward the high refractive index portion 625. On the other hand, the second slanted portion 627 is silicon oxynitride (SiON). In the second slanted portion 627, the ratio of nitrogen (N) to oxygen (O) continuously decreases from the high refractive index portion 625 toward the second low refractive index portion 629.

In this example, the thickness of each of the first low refractive index portion 621, the first slanted portion 623, the second slanted portion 627, and the second low refractive index portion 629 is 50 nm. Additionally, the thickness of the high refractive index portion 625 is 800 nm. In this way, in the first inorganic sealing layer 620, the thickness of the high refractive index portion 625 is thicker than the total film thickness of other portions (first low refractive index portion 621, first slanted portion 623, second slanted portion 627, and second low refractive index portion 629). By making the ratio of the high refractive index portion 625 larger in this way, the sealing effect of the silicon nitride is preferably improved. In addition, the dry etching processability of silicon nitride is better than that of silicon oxide. For this reason, the processability of the entire first inorganic sealing layer 620 may be improved by increasing the ratio of silicon nitride with respect to other portions.

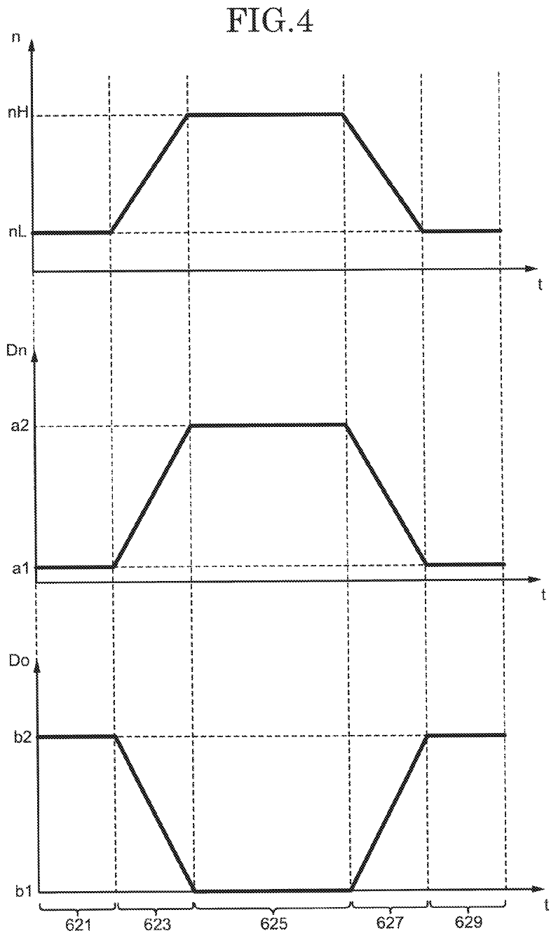

FIG. 4 is a diagram describing the characteristics of the first inorganic sealing layer according to a first embodiment of the present invention. FIG. 4 shows the changes of refractive index n, nitrogen concentration Dn, and oxygen concentration Do with respect to the thickness t direction of the first inorganic sealing layer 620 (first low refractive index portion 621, first slanted portion 623, high refractive index portion 625, second slanted portion 627, and second low refractive index portion 629).

The refractive index n shows the following tendency. In the first inorganic sealing layer 620, the refractive index n shows a lowest refractive index nL (1.4˜1.5) in the first low refractive index portion 621 and the second low refractive index portion 629, and shows a highest refractive index nH (1.7−1.9) in the high refractive index portion 625. In the first slanted portion 623, the refractive index continuously increases from nL to nH from the first low refractive index portion 621 towards the high refractive index portion 625 (moving away from the low refractive index layer 613). On the other hand, in the second slanted portion 627, the refractive index continuously decreases from nH to nL from the high refractive index portion 625 towards the second low refractive index portion 629 (moving away from the low refractive index layer 613).

Changes in the nitrogen concentration Dn and the oxygen concentration Do are as described above. That is to say, in the inorganic sealing layer 620, the nitrogen concentration Dn shows a lowest concentration a1 in the first low refractive index portion 621 and the second low refractive index portion 629, and shows a highest concentration a2 in the high refractive index portion 625. In the first slanted portion 623, the nitrogen concentration Dn continuously increases from a1 to a2 from the first low refractive index portion 621 towards the high refractive index portion 625. On the other hand, in the second slanted portion 627, the nitrogen concentration Dn continuously decreases from a2 to a1 from the high refractive index portion 625 towards the low refractive index portion 629. Furthermore, in this example, the first low refractive index portion 621 and the second low refractive index portion 629 include a small amount of nitrogen due to are created with a manufacturing method to be described below, however, are described as silicon oxide. As also shown in FIG. 4, portions including this small amount of nitrogen have the lowest nitrogen concentration Dn at least compared to that of other portions.

In the inorganic sealing layer 620, the oxygen concentration Do shows a highest concentration b2 in the first low refractive index portion 621 and the second low refractive index portion 629, and shows a lowest b1 in the high refractive index portion 625. The high refractive index portion 625 is silicon nitride, and so in principle b1 is 0, however, it may include a miniscule amount of oxygen. In the first slanted portion 623, the oxygen concentration Do continuously decreases from b2 to b1 from the first low refractive index portion 621 towards the high refractive index portion 625. On the other hand, in the second slanted portion 627, the oxygen concentration Do continuously increases from b1 to b2 from the high refractive index portion 625 towards the second low refractive index portion 629. Furthermore, the high refractive index portion 625 may be silicon oxinitride, however, the oxygen concentration Do is preferably low and the nitrogen concentration Dn is preferably high in the first inorganic sealing layer 620.

When the refractive index of the low refractive index layer 613 is n1 and the refractive index of the organic sealing layer 603 is n2, the relationship of the refractive index of each layer in the optical adjustment layer 601 preferably fulfills the following conditions.

nH>nL (1)

nH−n1>|nL−n1| (2)

nH−n2>|nL−n2| (3)

Further, the following conditions may also be fulfilled.

nH−nL>|nL−n1| (4)

nH−nL>|nL−n2| (5)

In this example, n1 is less than nL, and n2 is greater than nL, however, n1 and n2 may be greater than or less than nL. Additionally, n2 may be greater than n1, and n1 and n2 may be the same. Furthermore, when the refractive index of the high refractive index layer 611 is n3, n3 is greater than nH, however, n3 may be less than nH. In this case, n3 may be greater than nL and greater than n2.

In structure in which the low refractive index layer 613 is in contact with the first low refractive index portion 621 in the first inorganic sealing layer 620, the disparity between the refractive indexes of the two layers forming the interfaces decreases more so than in a structure in which the low refractive index layer 613 is in contact with the high refractive index portion 625 in the first inorganic sealing layer 620 (condition 2). Accordingly, the reflection on the interface when injected from the low refractive index layer 613 to the first inorganic sealing layer 620 may be suppressed. Similar to the relationship of the high refractive index layer 611 and the low refractive index layer 613 described above, by suppressing the reflection of light as much as possible other than on the interfaces in which it is necessary to actively cause reflection, the optical design may be simplified.

Additionally, the first inorganic sealing layer 620 may achieve a large sealing effect in the high refractive index portion 625. On the other hand, even when the refractive index of the high refractive index portion 625 greatly differs with respect to the low refractive index layer 613, the refractive index continuously changes in the first inorganic sealing layer 620 from the first low refractive index portion 621 towards the high refractive index portion 625. Accordingly, light injected to the first inorganic sealing layer 620 reaches the interface of the first inorganic sealing layer 620 and the organic sealing layer 603 without producing much reflection in the inner portion.

Additionally, in a structure in which the organic sealing layer 603 is in contact with the first low refractive index portion 621 in the first inorganic sealing layer 620, the disparity between the refractive indexes of the two layers forming the interface decreases more so than in a structure in which the organic sealing layer 603 is in contact with the high refractive index portion 625 in the first inorganic sealing layer 620 (condition (3)). Accordingly, reflection may be suppressed on the interface when injected from the first inorganic sealing layer 620 to the organic sealing layer 603.

### [Manufacturing Method of First Inorganic Sealing Layer]

In this example, the first inorganic sealing layer 620 is formed by CVD. At this time, with respect to the first slanted portion 623 and the second slanted portion 624, by changing the flow rate of gas used in film formation, the ratio of nitrogen and oxygen changes. An example of a manufacturing method of the first inorganic sealing layer 620 will be described below.

In this example, nitrogen (N₂) gas, mono-silane (SiH₄) gas, nitrous oxide (N₂O) gas, and ammonia (NH₃) gas are used. As is shown in the following Table 1, the first inorganic sealing layer 620 is formed by controlling the flow rate of these gasses. Because the flow rate described below is a relative value, units are not shown, however, according to a person having ordinary skill in the art, the first inorganic sealing layer 620 may be manufactured by appropriately setting the gas flow rate in a relationship with other various manufacturing parameters.

TABLE 1
The Gas Flow Rate of the Deposition Time
of the First Inorganic Sealing Layer 620

| Step | N₂ | SiH₄ | N₂O | NH₃ |
|---|---|---|---|---|
| 1 | 0 | 0.09 | 1.3 | 0 |
| 2 | 0 → 20 | 0.09 → 1.3 | 1.3 → 0 | 0 → 2 |
| 3 | 20 | 1.3 | 0 | 2 |
| 4 | 20 → 0 | 1.3 → 0.09 | 0 → 1.3 | 2 → 0 |
| 5 | 0 | 0.09 | 1.3 | 0 |

Steps 1-5 respectively correspond to the film formation of the first low refractive index portion 621 (silicon oxide), the first slanted portion 623 (silicon oxynitride), the high refractive index portion 625 (silicon nitride), the second slanted portion 624 (silicon nitride), and the second low refractive index portion 629 (silicon oxynitride).

In step 1, the flow rate of each gas is controlled so the nitrogen gas 0, the mono-silane gas 0.09, the nitrous oxide gas 1.3, and the ammonia gas 0. By this, silicon oxide which becomes the first low refractive index portion 621 is formed.

In step 2, the flow rate of gas changes from the state of step 1. Specifically, the flow rate of each gas is controlled so as to increase the nitrogen gas from 0 to 20, increase the mono-silane gas from 0.09 to 1.3, decrease the nitrous oxide gas from 1.3 to 0, and increase the ammonia gas from 0 to 2. By this, the composition of the first slanted portion 623 continuously changes from silicon oxide (first low refractive index portion 621), through silicon oxynitride, until becoming silicon nitride (high refractive index portion 625).

In step 3, the state of step 2 after control thereof is maintained, and the flow rate of each gas is controlled so the nitrogen gas is 20, the mono-silane gas is 1.3, the nitrous oxide gas is 0, and the ammonia gas is 2. During this time, hydrogen (H2) gas may be introduced. In this case, the flow rate may be 4. By doing so, a silicon nitride which becomes the high refractive index portion 625 is formed.

In step 4, the flow rate of the gas from the state of step 3 changes. Specifically, the flow rate of each gas is controlled so as to decrease the nitrogen gas from 20 to 0, decrease the mono-silane from 1.3 to 0.09, increase the nitrous oxide from 0 to 1.3, and decrease the ammonia gas from 2 to 0. By this, the composition of the second slanted portion 627 continuously changes from silicon nitride (high refractive index portion 625), through silicon oxynitride, until becoming silicon oxide (second low refractive index portion 629).

In step 5, the state o step 2 after control thereof is maintained, and the flow rate of each gas is controlled so the nitrogen gas 0, the mono-silane gas 0.09, the nitrous oxide gas 1.3, and the ammonia gas 0. By doing this, the silicon oxide which becomes the second low refractive index portion 629 is formed. By this, the first inorganic sealing layer 620 is formed above the low refractive index layer 613.

### Second Embodiment

In the first embodiment, the first low refractive index portion 621 and the second low refractive index portion 629 of the first inorganic sealing layer 620 have the same refractive index nL, however, they may have different refractive indexes.

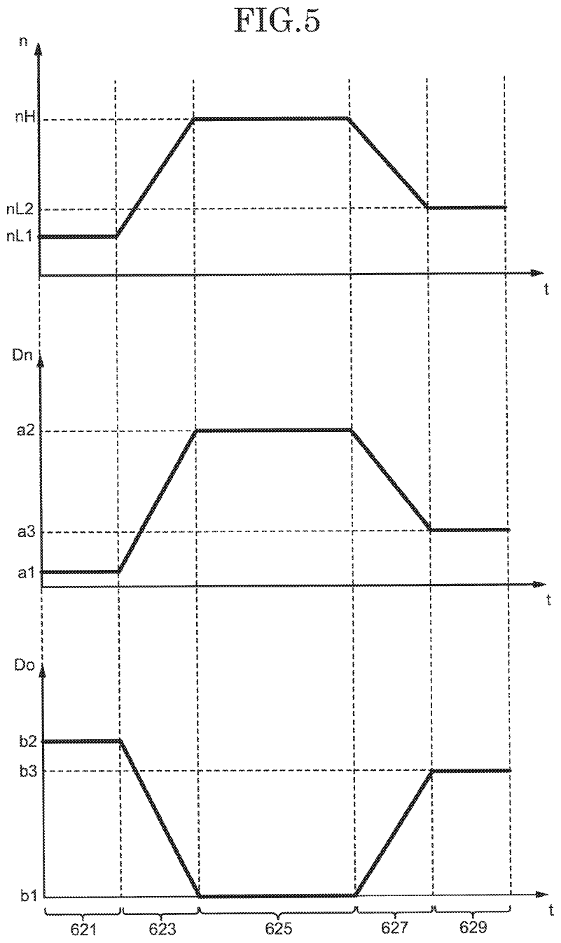

FIG. 5 is a diagram describing the characteristics of the first inorganic sealing layer according to a second embodiment of the present invention. FIG. 5 corresponds to FIG. 4 described in the first embodiment. A refractive index nL2 of the second low refractive index portion 629 according to the second embodiment is higher than a refractive index nL1 of the first low refractive index portion 621. nL2 is lower than nH, as in the first embodiment.

For this reason, the silicon oxynitride composing the second low refractive portion 629 is a film having more nitrogen and less oxygen than the silicon oxynitride composing the first low refractive index portion 621. As shown in FIG. 5, the nitrogen concentration Dn is a3 and the oxygen concentration Do is b3 in the second low refractive index portion 629. a3 is greater than a1 and less than a2. b3 is less than b2 and greater than b1. A film such as this may be formed by fixing the gas flow rate during the middle step (state before moving from state 4 to state 5) forming the second slanted portion 627 according to the first embodiment.

As described above, in this example, the organic sealing layer 603 is arranged on the second low refractive index portion 629 side of the first inorganic sealing layer 620. The refractive index of the organic sealing layer 603 is greater than each of the refractive indexes of the low refractive index layer 613 and the first low refractive index portion 621. Accordingly, the refractive index nL2 of the second low refractive index portion 629 may be close to the refractive index n2 of the organic sealing layer 603 by being greater than the refractive index nL of the second low refractive index portion 629 according to the first embodiment. Furthermore, depending on the combination of the layers above and below the first inorganic sealing layer 620, nL1 may be larger than nL2.

In this way, by the refractive index nL1 of the first low refractive index portion 621 and the refractive index nL2 of the second low refractive index portion 629 being different, even if the refractive indexes of the layers above and below the first inorganic sealing layer 620 differ, the reflection of light onto the interfaces above and below the first inorganic sealing layer 620 may be controlled.

### Modified Example

The exemplary embodiments of the present invention were described above, however, each of the above-mentioned embodiments may be combined or interchanged as appropriate. Additionally, each of the embodiments described above may be altered and implemented as described below.

(1) According to the embodiments described above, the first inorganic sealing layer 620 may be formed by silicon oxide, silicon oxynitride, or silicon nitride, however, may also be formed by other materials. The first inorganic sealing layer 620 may have the light transmissivity with respect to light from light emitting layer 513, and may have insulating properties. In order to easily form the first slanted portion 623 and the second slanted portion 627, like the combination of oxygen and nitrogen, materials in which the refractive index changes by adjusting the ratio of two components may be used in the first inorganic sealing layer 620. Furthermore, materials in which the refractive index changes by adjusting the ratio of at least one component may be used in the first inorganic sealing layer 620.

(2) The first inorganic sealing layer 620 is formed by forming film continuously from the first low refractive index portion 621 to the second low refractive index portion 629, however, film may also not be formed continuously. For example, film formation may form halfway to the high refractive index portion 625, and after other processes have occurred, start forming once again halfway from the high refractive index portion 625. As long as the structure of the first inorganic sealing layer 620 shown in FIG. 3 in the light emitting region LA is implemented, structures such as wirings outside of the light emitting region LA may be arranged by other processes as layers between the first inorganic sealing layer 620.

(3) As long as the refractive index in at least one portion continuously changes in the first slanted portion 623 and the second slanted portion 627 within the first inorganic sealing layer 620, a position may be included in which the refractive index does not continuously change. In this case, a position in which the nitrogen concentration Dn and the oxygen concentration Do do not continuously change would be included in the first slanted portion 623 and the second slanted portion 627. When this happens, the amount of change of the refractive index at the position which is not continuously changing is preferably less than that of the disparity of n1 and n2 described above.

(4) In the embodiments described above, the second inorganic sealing layer 605 is formed of silicon nitride, however, may also be formed by the same structure as the first inorganic sealing layer 620. That is to say, the second inorganic sealing layer 605 may have, in order from the organic sealing layer 603 side, a stacked structure corresponding to the first low refractive index portion 621, the first slanted portion 623, the high refractive index portion 625, the second slanted portion 627, and the second low refractive index portion 629 (hereinafter referred to as first refractive index portion 621A, first slanted portion 623A, high refractive index portion 625A, second slanted portion 627A, and second low refractive index portion 629A).

In this example, the layer below the second inorganic sealing layer 605 is the organic sealing layer 603, and the layer above the second inorganic sealing layer 605 is the organic insulating layer 650. Accordingly, the first low refractive index portion 621A is formed of material having a similar refractive index to that of the organic sealing layer 603, and the second low refractive index portion 629 may be formed by material having a refractive index similar to that of the organic insulating layer 650. For example, the first low refractive index portion 621A and the second low refractive index portion 629A may be silicon oxide, and, may also be silicon oxynitride in which the ratio of oxygen and nitrogen is set so as to have a desirable refractive index.

Furthermore, the first insulating layer 850 may be formed of a similar structure to that of the first inorganic sealing layer 620. In this way, the structure of the first inorganic sealing layer 620 may be applied to other layers in the region through which light from the light emitting layer 513 passes.

In the embodiments described above, the second substrate 2 does may not be used. In this case, the second low refractive index portion 629 in the first inorganic sealing layer 620 may be the outermost surface. Because the refractive index of the atmosphere is low, the reflection of the interface may be suppressed rather than the high refractive index portion 625 being the outermost surface.

According to the embodiments described above, a touch sensor 800 may not be used.

The first inorganic sealing layer 620, the organic sealing layer 603, and the inorganic sealing layer 605 function as layers inhibiting the arrival of elements which deteriorate the light emitting portion 510, however, the second inorganic sealing layer 605 may not be necessary, and the organic sealing layer 603 may further not be necessary.

Other variations and modifications may be conceived by those skilled in the art within the spirit of the present invention, and it is understood that all such variations and modifications also fall within the scope of the invention. For example, those skilled in the art may appropriately modify each of the above embodiments by addition, deletion, or design change of structural elements, or by adding, omitting, or altering steps, and all such modifications also fall within the scope of the invention as long as they come within the spirit of the present invention.

What is claimed is:

1. A display device comprising:
a light emitting layer emitting light in response to a supplied electric current;
a first insulating layer arranged above a path of light emitted from the light emitting layer, having a first refractive index; and
a second insulating layer including a first portion arranged in contact with the first insulating layer on an opposite side of the light emitting layer with respect to the first insulating layer, and a second portion arranged further from the first insulating layer than the first portion, wherein
a refractive index of the first portion increases from a second refractive index to a third refractive index the further away from the first insulating layer, a refractive index of the second portion decreases from the third refractive index to a fourth refractive index the further away from the first insulating layer, and the refractive index of the first portion continuously changes in at least one portion of the first portion and the refractive index of the second portion continuously changes at least one portion of the second portion.

2. The display device according to claim 1, wherein a difference between the first refractive index and the second refractive index is smaller than a difference between the first refractive index and the third refractive index.

3. The display device according to claim 1, wherein the first refractive index is lower than the second refractive index.

4. The display device according to claim 1, wherein
the first portion includes silicon oxynitride, and
a ratio of nitrogen to oxygen increases the further the first portion is from the first insulating layer.

5. The display device according to claim 1, wherein
the second portion includes silicon oxynitride, and
a ratio of nitrogen to oxygen decreases the further the second portion is from the first insulating layer.

6. The display device according to claim 1, wherein the second insulating layer has a third portion including silicon nitride between the first portion and the second portion.

7. The display device according to claim 6, wherein a thickness of the third portion is thicker than a total thickness of the first portion and the second portion.

8. The display device according to claim 1, wherein the second refractive index is lower than the fourth refractive index.

9. The display device according to claim 1, wherein the second refractive index is the same as the fourth refractive index.

10. The display device according to claim 1, further comprising:
a third insulating layer having a refractive index higher than the third refractive index, arranged in contact with the first insulating layer on the opposite side of the second insulating layer with respect to the first insulating layer.

11. The display device according to claim 10, wherein
the light emitting layer includes a first light emitting layer emitting a first light in response to a supplied electric current, and a second light emitting layer emitting a second light in a different color to the first light in response to a supplied electric current;
the first insulating layer is arranged above a path of light of the first light and the second light, and
a thickness of the third insulating layer in a region through which the first light passes differs from a thickness of the third insulating layer in a region through which the second light passes.

12. The display device according to claim 1, further comprising:
a fourth insulating layer having a fifth refractive index arranged in contact with the second insulating layer on the opposite side of the first insulating layer with respect to the second insulating layer, wherein
a difference between the fifth refractive index and the fourth refractive index is smaller than a difference between the fifth refractive index and the third refractive index.

13. The display device according to claim 12, wherein the fifth refractive index is higher than the fourth refractive index.

14. The display device according to claim 12, wherein the fourth insulating layer is an organic insulating layer.

15. The display device according to claim 14, further comprising:
a fifth insulating layer arranged on the opposite side of the second insulating layer with respect to the fourth insulating layer, including a fourth portion in which a refractive index thereof increases the further away from the second insulating layer, and a fifth portion in which a refractive index thereof decreases the further away from the second insulating layer, wherein a refractive index continuously changes in at least one portion of the fourth portion and at least one portion of the fifth portion.

16. A display device comprising:
a light emitting layer emitting light in response to a supplied electric current;
a first insulating layer arranged above a path of light emitted from the light emitting layer;
a second insulating layer including a first portion arranged in contact with the first insulating layer on the opposite side of the light emitting layer with respect to the first insulating layer, and a second portion arranged further from the first insulating layer than the first portion,
wherein a ratio of nitrogen to oxygen of the first portion increases the further away from the first insulating layer, a ratio of nitrogen to oxygen of the second portion decreases the further away from the first insulating layer, and the ratios continuously change in at least one portion of the first portion and at least one portion of the second portion.

17. The display device according to claim 16, wherein the first portion and the second portion include silicon oxynitride.

18. The display device according to claim 17, wherein the second insulating layer has a third portion including silicon nitride between the first portion and the second portion.

19. The display device according to claim 18, wherein a thickness of the third portion is thicker than a total thickness of the first portion and the second portion.

20. The display device according to claim 16, further comprising:
a third insulating layer having a higher refractive index than the first insulating layer arranged in contact with the first insulating layer on the opposite side of the second insulating layer with respect to the first insulating layer, wherein
the light emitting layer includes a first light emitting layer emitting a first light in response to a supplied electric current, and a second light emitting layer emitting a second light of a different color to the first light in response to a supplied electric current,
the first insulating layer is arranged above a path of the first light and the second light, and
a thickness of the third insulating layer in a region through which the first light passes differs from a thickness of the third insulating layer in a region through which the second light passes.
